(19) United States
(12) Patent Application Publication
(10) Pub. No.: US 2023/0236732 A1
(43) Pub. Date: Jul. 27, 2023

(54) MEMORY DEVICE

(71) Applicant: SAMSUNG ELECTRONICS CO., LTD., SUWON-SI (KR)

(72) Inventors: SUK HAN LEE, SEOUL (KR); SHIN HAENG KANG, SUWON-SI (KR); KYO MIN SOHN, YONGIN-SI (KR)

(21) Appl. No.: 17/975,250

(22) Filed: Oct. 27, 2022

(30) Foreign Application Priority Data
Jan. 26, 2022 (KR) 10-2022-0011466

(51) Int. Cl. G06F 3/06

(52) U.S. Cl. CPC G06F 3/0613; G06F 3/0629; G06F 3/0673; G06F 3/0659

(57) ABSTRACT

A memory device is provided. The memory device comprises a memory cell array configured to store data, a command decoder configured to receive a command from the exterior to generate a first memory cell control signal, a PIM (Processor In Memory) block configured to generate a second memory cell control signal including a command for performing an internal processing operation on the basis of instructions stored therein and perform an internal processing operation on the basis of the second memory cell control signal, and an operating mode multiplexer configured to output any one of the first memory cell control signal and the second memory cell control signal and provide it to the memory cell array.

### CROSS-REFERENCE TO RELATED APPLICATION

This application claims priority from Korean Patent Application No. 10-2022-0011466, filed on Jan. 26, 2022, in the Korean Intellectual Property Office, the disclosure of which is incorporated herein by reference in it's entirety.

### BACKGROUND

### 1. Technical Field

The present disclosure relates to a memory device. Specifically, the present disclosure relates to a memory device including a PIM (Processor In Memory) block.

### 2. Description of the Related Art

A semiconductor memory device for storing data may be broadly classified into a volatile memory device and a non-volatile memory device. In the volatile memory device such as a DRAM (Dynamic Random Access Memory), in which data is stored by charging or discharging of a cell capacitor, the stored data is kept while a power is applied, but the stored data is lost when the power is cut off. On the other hand, the non-volatile memory device may store data even when the power is cut off. The volatile memory device is mainly used as a main memory for a computer or the like, and the non-volatile memory device is used as a large-capacity memory which stores and programs data in a wide range of application devices such as a computer and a portable communication devices.

On the other hand, among the volatile memory devices, the DRAM may exhibit the characteristics of relatively fast response speed and fast operating speed. Accordingly, the DRAM tends to be widely used as the operating memory or the main memory of a memory system.

On the other hand, while the computer operation performed on the host is relatively fast, since the operation of retrieving and writing instructions or data from the DRAM is relatively slow, the performance of the overall memory system may slow down.

Accordingly, a memory device including an internal processor so that a part of a computing operation of the host is performed by internal processing has been developed to improve the performance of the memory system, and an operating burden of a host computer may be reduced through the internal processing of the memory device.

However, it is necessary to improve the performance of the operation of reading or writing the data stored in the memory cell of the memory device required for performing the internal processing operation.

### SUMMARY

Aspects of the present disclosure provide a memory device in which the performance of the internal data processing operation inside a memory device is improved.

Aspects of the present disclosure also provide a memory system in which performance of the internal data processing operation performed inside the memory device is improved.

According to some aspects of the present disclosure, there is a provided memory device comprising a memory cell array configured to store data, a command decoder configured to receive an external command to generate a first memory cell control signal, a PIM (Processor In Memory) block configured to generate a second memory cell control signal including a command for performing an internal processing operation on the basis of an instruction stored internally, and perform an internal processing operation on the basis of the second memory cell control signal, and an operating mode multiplexer configured to output any one of the first memory cell control signal and the second memory cell control signal and provide them to the memory cell array.

According to some aspects of the present disclosure, there is provided a memory device comprising a PIM (Processor In Memory) block configured to include an instruction register configured to store instructions to perform particular internal processing operations in a pre-coded state, and a command generator configured to receive the instructions from the instruction register and generate a first memory cell control signal on the basis of the instructions, wherein the PIM block reads data for performing the internal processing operation on the basis of the first memory cell control signal from a memory cell array, the PIM block performs the internal processing operation, and the PIM block writes data for which the internal processing operation is completed for use by the memory cell array.

According to some aspects of the present disclosure, there is a provided memory system comprising a memory controller configured to provide a command and an address, and a memory device configured to receive the command and the address from the memory controller and transmit and receive data to and from the memory controller, wherein the memory device includes a memory cell array that stores data, and a PIM (Processor In Memory) block that generates a first memory cell control signal including a command for performing an internal processing operation on the basis of an instruction stored inside, and performs the internal processing operation on the basis of the first memory cell control signal, wherein the PIM reads data for performing the internal processing operation on the basis of the first memory cell control signal from the memory cell array or writes data for which the internal processing operation is completed for use by the memory cell array.

However, aspects of the present disclosure are not restricted to the ones set forth herein. The above and other aspects of the present disclosure will become more apparent to one of ordinary skill in the art to which the present disclosure pertains by referencing the detailed description of the present disclosure as described below.

### BRIEF DESCRIPTION OF THE DRAWINGS

FIG. 1 is an exemplary block diagram for explaining a memory system according to some embodiments.

FIG. 2 is an exemplary block diagram for explaining the memory device according to some embodiments of FIG. 1.

FIG. 3 is an exemplary block diagram for explaining a memory device according to some embodiments.

FIG. 4 is an exemplary block diagram for explaining a PIM block according to some embodiments.

FIG. 5 is an exemplary diagram for showing the operation of the PIM block according to some embodiments.

FIG. 6 is an exemplary diagram for showing the operation of the memory device according to some embodiments.

FIG. 7 is an exemplary block diagram for explaining a PIM block according to some other embodiments.

FIG. 8 is an exemplary flowchart for explaining the operation of the memory system according to some embodiments.

FIG. 9 is an exemplary block diagram for explaining a memory system according to some other embodiments.

FIG. 10 is an exemplary block diagram which shows a data center according to some embodiments.

### DETAILED DESCRIPTION OF PREFERRED THE EMBODIMENTS

Hereinafter, embodiments according to the technical concepts of the present disclosure will be described referring to the accompanying drawings.

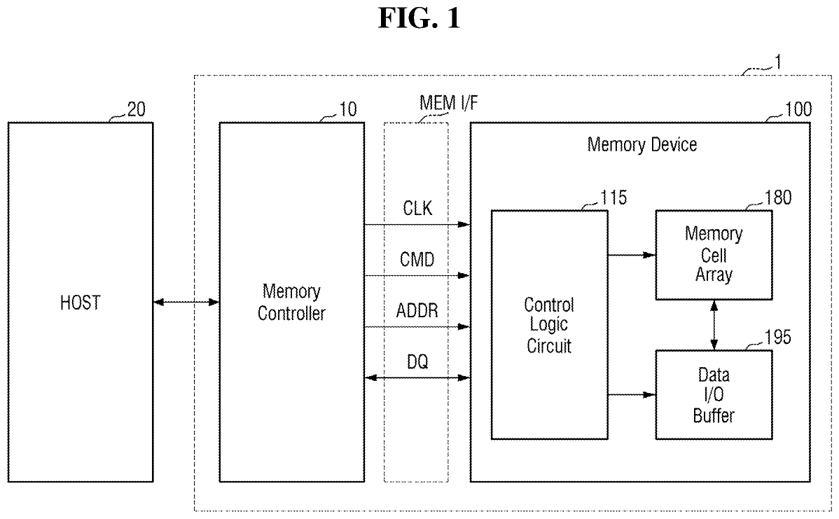

FIG. 1 is an exemplary block diagram for explaining a memory system according to some embodiments.

Referring to FIG. 1, the memory system may include a host 20 and a memory storage device 1. The memory storage device 1 may include a memory device 100 and a memory controller 10.

The memory controller 10 may generally control the operation of the memory device 100. For example, the memory controller 10 may control a data exchange between the external host 20 and the memory device 100. For example, the memory controller 10 may control the memory device 100 in response to a request of the host 20, and may write or read the data through the memory device 100.

The memory controller 10 and the memory device 100 may communicate with each other through the memory interface (MEM I/F). Further, the memory controller 10 and the external host 20 may communicate with each other through a host interface. That is, the memory controller 10 may mediate a signal between the memory device 100 and the host 20. The memory controller 10 may control the operation of the memory device 100 by applying a command CMD for controlling the memory device 100.

Here, the memory device 100 may include dynamic memory cells. For example, the memory device 100 may include a DRAM (dynamic random access memory), a DDR4 (double data rate 4) SDRAM (synchronous DRAM), a LPDDR4 (low power DDR4) SDRAM, an LPDDR5 SDRAM, and the like.

However, the embodiment according to the technical concept of the present disclosure is not limited thereto, and the memory device 100 may include a non-volatile memory device. However, in this embodiment, the memory device 100 will be described as a volatile memory device.

The memory controller 10 may transmit a clock signal CLK, a command CMD, an address ADDR, and the like to the memory device 100. The memory controller 10 may provide data DQ to the memory device 100, and may receive the data DQ from the memory device 100. The memory device 100 may include a memory cell array 180 in which data DQ is stored, a control logic circuit 115, a data I/O buffer 195, and the like.

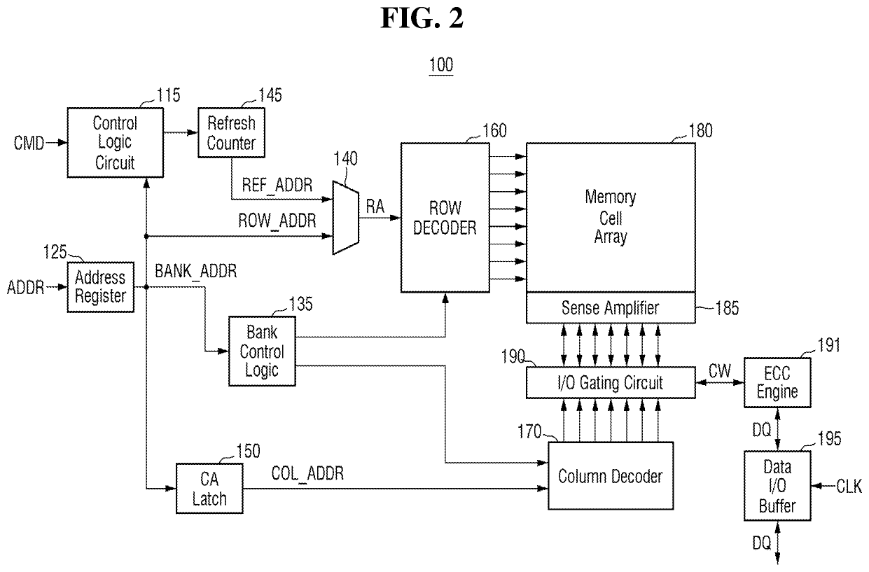

FIG. 2 is an exemplary block diagram for explaining the memory device according to some embodiments of FIG. 1.

Referring to FIG. 2, the memory device 100 may include a control logic circuit 115, an address register 125, a bank control logic circuit 135, a row address multiplexer 140, a refresh counter 145, a column address latch 150, a row decoder 160, a column decoder 170, a memory cell array 180, a sense amplifier 185, an I/O gating circuit 190, an ECC engine 191, and a data I/O buffer 195.

The memory cell array 180 may include a plurality of bank arrays. The row decoder 160 may be connected to a plurality of bank arrays. The column decoder 170 may be connected to a plurality of bank arrays. The sense amplifier 185 may be connected to each of a plurality of bank arrays. The memory cell array 180 may include a plurality of word lines, a plurality of bit lines, and a plurality of memory cells formed at points on which the word lines and bit lines intersect.

The address register 125 may receive an address ADDR from the memory controller. The address ADDR may include a bank address BANK_ADDR, a row address ROW_ADDR, a column address COL_ADDR, and the like. The address register 125 may provide the bank address BANK_ADDR to the bank control logic circuit 135. The address register 125 may provide the row address ROW_ADDR to the row address multiplexer 140. The address register 125 may provide the column address COL_ADDR to the column address latch 150.

The bank control logic circuit 135 may generate bank control signals in response to the bank address BANK_ADDR. The row decoder 160 may be activated in response to a bank control signal. Further, the column decoder 170 may be activated in response to the bank control signal corresponding to the bank address BANK_ADDR.

The row address multiplexer 140 may receive the row address ROW_ADDR from the address register 125 and receive a refresh row address REF_ADDR from the refresh counter 145. The row address multiplexer 140 may select either the row address ROW_ADDR or the refresh row address REF_ADDR and output it to the row address RA. The row address RA may be transferred to the row decoder 160.

The refresh counter 145 may sequentially output the refresh row address REF_ADDR according to the control of the control logic circuit 115.

The row decoder 160 activated by the bank control logic circuit 135 may decode the row address RA output from the row address multiplexer 140 and activate the word line corresponding to the row address RA. For example, the row decoder 160 may apply a word line drive voltage to the word line corresponding to the row address RA.

The column address latch 150 may receive the column address COL_ADDR from the address register 125 and temporarily store the received column address COL_ADDR. The column address latch 150 may gradually increase the column address COL_ADDR received in a burst mode. The column address latch 150 may provide the column decoder 170 with a temporarily stored column address COL_ADDR or a gradually increased column address COL_ADDR.

Among the column decoders 170, the column decoder 170 activated by the bank control logic circuit 135 may activate the sense amplifier 185 corresponding to the bank address BANK_ADDR and the column address COL_ADDR through the corresponding I/O gating circuit 190.

The I/O gating circuit 190 may include a circuit for gating the I/O data, an input data mask logic, a read data latch for storing the data output from the memory cell array 180, and write drivers for writing the data to the memory cell array 180.

A code word CW that is read from the bank array of the memory cell array 180 may be sensed by the sense amplifier 185 corresponding to the bank array. In addition, the code word CW may be stored in a read data latch. The code word CW stored in the read data latch may be subjected to ECC decoding by the ECC engine 191, and the data DQ subjected to the ECC decoding may be provided to the memory controller 10 through the data I/O buffer 195.

The data I/O buffer 195 may provide the data DQ to the ECC engine 191 on the basis of the clock signal CLK in the write operation. The data I/O buffer 195 may provide the data DQ provided from the ECC engine 191 to the memory controller 10 on the basis of the clock signal CLK in the read operation.

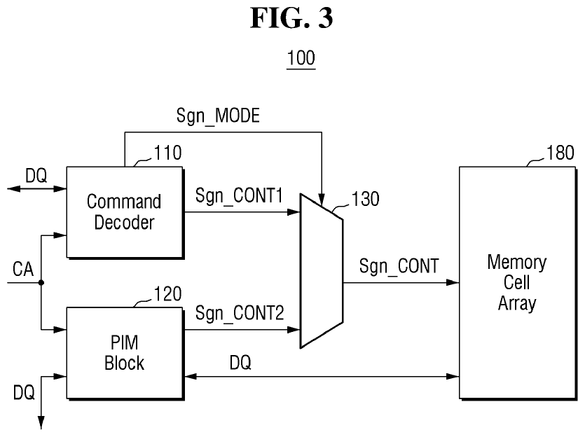

FIG. 3 is an exemplary block diagram for explaining a memory device according to some embodiments.

Referring to FIG. 3, the memory device 100 may include a command decoder 110, a PIM block 120 (Processor In Memory Block), an operating mode multiplexer 130, and a memory cell array 180.

The command decoder 110 may receive the command/address CA. For example, the command decoder 110 may receive the command/address CA from the memory controller 10 shown in FIG. 1.

The command decoder 110 may output an operating mode signal Sgn_MODE and a first memory cell control signal Sgn_CONT1 on the basis of the received command/address CA. The command decoder 110 may provide the operating mode signal Sgn_MODE and the first memory cell control signal Sgn_CONT1 to the operating mode multiplexer 130.

The PIM block 120 may be implemented by a computation-intensive core, a GPU accelerator, an FPGA (field programmable gate array), or the like. Alternatively, although the PIM block 120 may be implemented as an NPU (Neural Processing Unit) that performs parallel computing, data reuse, locality of data values or a deep neural network, the embodiment is not limited thereto.

The PIM block 120 may receive the command/address CA externally. For example, the PIM block 120 may directly receive the command/address CA from the memory controller 10 shown in FIG. 1.

The PIM block 120 may output a second memory cell control signal Sgn_CONT2 generated internally on the basis of the received command/address CA. The PIM block 120 may provide the second memory cell control signal Sgn_CONT2 to the operating mode multiplexer 130.

On the other hand, although FIG. 3 shows that the PIM block 120 receives the command/address CA and outputs the second memory cell control signal Sgn_CONT2 on the basis of the command/address CA, the embodiment is not limited thereto. For example, the PIM block 120 may generate a command for performing an internal processing operation, using internally stored instructions, without receiving the command/address CA externally. In this case, the command for performing the internal processing operation may be the second memory cell control signal Sgn_CONT2. The instructions may be stored in an instruction register inside the PIM block 120. The specific contents thereof will be described later.

As described above, the memory device according to some embodiments of the present disclosure can solve the problem that the existing command received from the outside and the internal instructions necessarily need to match, because the PIM block 120 generates the command for performing the internal processing operation by itself and internally, without receiving the command/address CA externally.

The operating mode multiplexer 130 may receive the first memory cell control signal Sgn_CONT1 from the command decoder 110, and receive the second memory cell control signal Sgn_CONT2 from the PIM block 120.

The operating mode multiplexer 130 may output the memory cell control signal Sgn_CONT on the basis of the operating mode signal Sgn_MODE received from the command decoder 110. For example, the operating mode multiplexer 130 may output any one of the first memory cell control signal Sgn_CONT1 and the second memory cell control signal Sgn_CONT2 as the memory cell control signal Sgn_CONT on the basis of the operating mode signal Sgn_MODE. The operating mode multiplexer 130 may provide the memory cell control signal Sgn_CONT to the memory cell array 180.

On the other hand, although FIG. 3 shows that the operating mode multiplexer 130 outputs the memory cell control signal Sgn_CONT on the basis of the operating mode signal Sgn_MODE received from the command decoder 110, the embodiment is not limited thereto. For example, the command decoder 110 may directly provide the first memory cell control signal Sgn_CONT1 for performing a data transaction to the memory cell array 180, and the PIM block 120 may also provide the second memory cell control signal Sgn_CONT2 for performing the internal processing operation directly to the memory cell array 180.

The memory cell array 180 may be the same as that described in FIGS. 1 and 2. Although the memory cell array 180 may include, for example, a DRAM memory cell including a capacitor and a transistor, the embodiment is not limited thereto.

The memory device 100 may operate in either a general operating mode in which the data transaction operation of the read and write operation of data is performed, or an internal processing operating mode in which the internal processing operation is performed. That is, the memory device 100 may be a PIM type memory device 100 including a processor-in-memory that performs the internal processing operation.

For example, the memory device 100 may write the data DQ provided externally to the memory cell array 180 in the general operating mode, or read the data DQ stored in the memory cell array 180 and transmit the data DQ to the exterior. That is, the command decoder 110 shown in FIG. 3 may include various configurations for performing read and write operations of data such as the control logic circuit 115 described in FIGS. 1 and 2.

On the other hand, for example, the memory device 100 may perform the processing operation on data stored in the memory cell array 180 through the PIM block 120 in the internal processing operating mode. That is, in FIG. 3, the command/address CA received by the command decoder 110 and the PIM block 120 may include a signal that not only instructs the read or write operation of data to the memory cell array 180 through the command decoder 110, but also instructs the PIM block 120 to perform the internal processing operation. Alternatively, as described above, the PIM block 120 may not only receive the command/address CA that instructs to perform the internal processing operation as described above, but also generates a command for performing the internal processing operation using the instructions stored inside.

Further, the memory cell array 180 may store internal processing information. For example, the memory cell array 180 may store the internal processing information for the internal processing operation performed by the PIM block 120. The internal processing information may include, for example, an internal processing operation command and internal processing data, but the embodiment is not limited thereto.

Further, in order to perform the internal processing operation of the PIM block 120, the command/address CA may include a command such as an internal processing read command or an internal processing write command. Alternatively, as described above, the PIM block 120 may generate commands such as an internal processing read command or an internal processing write command by itself internally.

The PIM block 120 may perform processing operations such as a MAC (Multiplying-Accumulating) computation, a data inversion, a data shift, a data swap, a data comparison, and various logical operations (AND, XOR etc.), and numerical operations (mathematical operations, addition, subtraction, etc.).

The memory device 100 performs different operations in the general operating mode and the internal processing operating mode, and the operating mode multiplexer 130 may output the memory cell control signal Sgn_CONT on the basis of the operating mode signal Sgn_MODE.

For example, in response to the operating mode signal Sgn_MODE being the general operating mode, the operating mode multiplexer 130 may output the first memory cell control signal Sgn_CONT1 output from the command decoder 110 as the memory cell control signal Sgn_CONT. Accordingly, the data DQ may be written to the memory cell array 180 or the data DQ stored in the memory cell array 180 may be read.

On the other hand, for example, in response to the operating mode signal Sgn_MODE being the internal processing operating mode, the operating mode multiplexer 130 may output the second memory cell control signal Sgn_CONT2 output from the PIM block 120 as the memory cell control signal Sgn_CONT. Therefore, the PIM block 120 may read the data DQ for performing the internal processing operation from the memory cell array 180, or may write the data DQ for which the internal processing operation is completed for the memory cell array.

The operating mode signal Sgn_MODE may include a combination of a plurality of signals such as a command combination, a mode register set (MRS), and an address combination, but this embodiment is not limited thereto. Although the operating mode signal Sgn_MODE is shown to be output from the command decoder 110 in FIG. 3, the embodiment is not limited thereto, and the operating mode signal Sgn_MODE may be output externally such as from the memory controller 10 of FIG. 1, and provided to the operating mode multiplexer 130.

An existing data flow between the PIM block 120 and the memory cell array 180 was determined by the command decoded in the command decoder 110. However, the memory device 100 according to some embodiments of the present disclosure may directly generate the memory cell control signal inside the PIM block 120 to control the memory cell array 180, when the internal processing operation is performed in the PIM block 120. Therefore, unlike the existing memory device including the PIM, the PIM block 120 may control the data flow from the memory cell array 180 and the exterior regardless of the command decoder 110 when performing the internal processing operation. Therefore, it is possible to improve the internal processing operation performance using the PIM block 120 of the memory device 100.

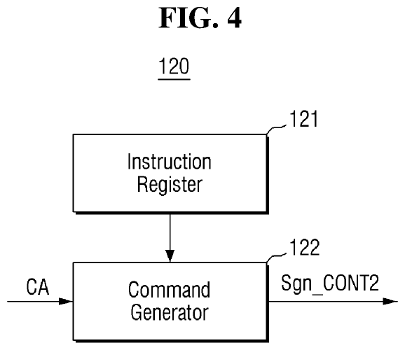

FIG. 4 is an exemplary block diagram for explaining a PIM block according to some embodiments.

Referring to FIG. 4, the PIM block 120 may include an instruction register 121 and a command generator 122.

The instruction register 121 may store pre-coded instructions. The instruction register 121 may provide the stored instructions to the command generator 122.

The command generator 122 may receive the command/address CA from the exterior and generate the second memory cell control signal Sgn_CONT2 on the basis of the command/address CA. Alternatively, the command generator 122 may receive an instruction from the instruction register 121 and generate the second memory cell control signal Sgn_CONT2 on the basis of the instructions. That is, the command generator 122 may generate commands for performing the internal processing operations by itself and internally, without providing the command/address CA from the exterior.

That is, when the PIM block 120 performs the internal processing operation, the instruction register 121 may store the instructions corresponding to each of the internal processing operations in a pre-coded state. The command generator 122 may output the second memory cell control signal Sgn_CONT2 that controls the memory cell array 180 so that the PIM block 120 performs the particular internal processing operation, on the basis of the order or type of instructions.

On the other hand, although not shown, the PIM block 120 may include an operator that performs the internal processing operation. The operator may perform the internal processing operation, for example, an operation such as a MAC computation.

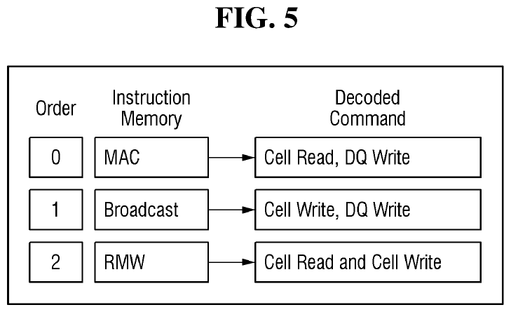

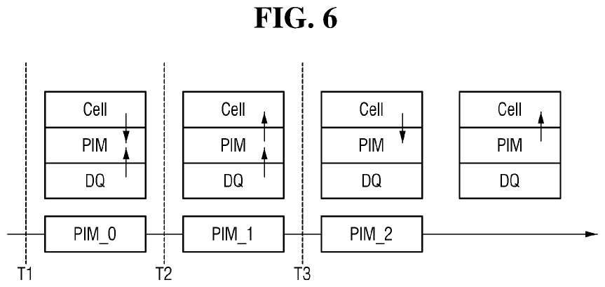

FIG. 5 is an exemplary diagram for showing the operation of the PIM block according to some embodiments, and FIG. 6 is an exemplary diagram for showing the operation of the memory device according to some embodiments.

Referring to FIGS. 5 and 6, first, as shown in FIG. 5, it is assumed that three instructions are stored in the instruction register 121. In this case, it is assumed that the three instructions may be named MAC, Broadcast, and RMW, respectively.

The instruction register 121 stores three instructions, and the instructions may have a predetermined order. For example, after the internal processing operation corresponding to the MAC instruction is performed, the internal processing operation corresponding to the Broadcast instruction is performed, and after the internal processing operation corresponding to the Broadcast instruction is performed, the internal processing operation corresponding to the RMW instruction may be performed.

For example, referring to FIG. 6 together, a 0th internal processing operation PIM_0 corresponding to the MAC instruction may be performed at the first time point T1. Next, after the 0th internal processing operation PIM_0 corresponding to the MAC instruction is performed, the first internal processing operation PIM_1 corresponding to the Broadcast instruction may be performed at a second time point T2. Next, after the first internal processing operation PIM_1 corresponding to the Broadcast instruction is performed, the second internal processing operation PIM_2 corresponding to the RMW instruction may be performed at a third time point T3.

On the other hand, referring to FIG. 5 again, the MAC instruction may instruct an internal processing operation including an operation of reading the data from the memory cell array and writing the data from the exterior to the PIM block.

The broadcast instruction may instruct an internal processing operation including an operation of writing the data computed through the internal processing operation to the memory cell array and writing the data from the exterior to the PIM block.

The RMW instruction may instruct an internal processing operation including an operation of reading the data from the memory cell array and writing the data computed through the internal processing operation to the memory cell array again.

For example, referring to FIG. 6 together, the 0th internal processing operation PIM_0 corresponding to the MAC instruction may be performed at the first time point T1. That is, the 0th internal processing operation PIM_0 may mean an operation of reading the data from the memory cell array Cell to the PIM block PIM and writing the data DQ from the exterior to the PIM block PIM.

Next, at the second time point T2, the first internal processing operation PIM_1 corresponding to the Broadcast instruction may be performed. That is, the first internal processing operation PIM_1 may mean an operation of writing the data computed through the internal processing operation inside the PIM block PIM to the memory cell array Cell and writing the data DQ from the exterior to the PIM block PIM.

Next, the second internal processing operation PIM_2 corresponding to the RMW instruction may be performed at the third time point T3. That is, the second internal processing operation PIM_2 may mean an operation of reading the data from the memory cell array Cell to the PIM block PIM and writing the data computed through the internal processing operation inside the PIM block PIM to the memory cell array Cell again.

However, this is only for convenience of explanation, and the examples are not limited to the aforementioned description. For example, the PIM block may include a different number of instructions, and there may be various internal processing operations corresponding to the instructions. Further, although FIGS. 5 and 6 show that the internal processing operation is performed according to the order of predetermined instruction, it is clear that the embodiments are not limited thereto.

As described above, when the PIM block PIM performs the internal processing operation, the command for the internal processing operation may be generated using the instruction stored in the instruction register, without providing the external command/address. This makes it possible to simultaneously use the data transferred from the exterior, which is necessary for performing the internal processing operation in the PIM block PIM, and the data that is read from the memory cell array, thereby improving the overall performance of the memory device.

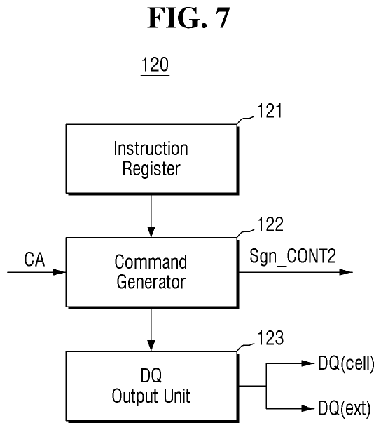

FIG. 7 is an exemplary block diagram for explaining a PIM block according to some other embodiments. The repeated contents of those described in connection with FIG. 4 will be omitted as redundant, and focus will be on the differences.

Referring to FIG. 7, the PIM block 120 may further include a data output unit 123 (DQ output unit).

The data output unit 123 may transmit the data DQ for which the internal processing operation is completed to either the external (ext) or the memory cell array (cell) by the control of the command generator 122.

For example, when the PIM block 120 performs the internal processing operation and transmits the data DQ for which the internal processing operation is completed, the data output unit 123 may include a multiplexer (MUX) for transmitting the data DQ to the external (ext) or the memory cell array (cell) by the control of the command generator 122.

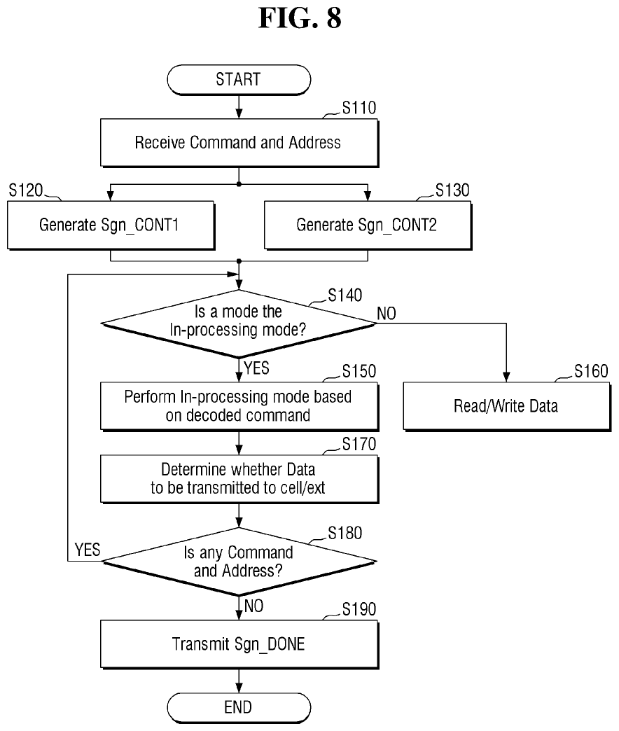

FIG. 8 is an exemplary flowchart for explaining the operation of the memory system according to some embodiments.

Referring to FIG. 8, the command decoder 110 and the PIM block 120 may receive the command/address CA that is output from the memory controller 10 (S110).

Subsequently, the command decoder 110 may generate the first memory cell control signal Sgn_CONT1 on the basis of the received command/address CA (S120), and the PIM block 120 may generate the second memory cell control signal Sgn_CONT2 on the basis of the received command/address CA (S130).

On the other hand, although FIG. 8 shows that the PIM block 120 generates the second memory cell control signal Sgn_CONT2 on the basis of the received command/address CA, the embodiment is not limited thereto. As described in FIGS. 3 to 7, the PIM block 120 may generate the second memory cell control signal Sgn_CONT2 without receiving the command/address CA, and therefore, the description thereof will not repeated as redundant.

Subsequently, it may be determined whether the operating mode of the memory device 100 is the internal processing operating mode (S140). For example, the operating mode multiplexer 130 may receive the operating mode signal Sgn_MODE from the command decoder 110, and output one of the first memory cell control signal Sgn_CONT1 and the second memory cell control signal Sgn_CONT2 to the memory cell array 180 on the basis of the operating mode signal Sgn_MODE.

For example, when the operating mode of the memory device 100 is the internal processing operating mode (YES of S140), the memory device 100 may perform the internal processing operation on the basis of the command generated by the command generator 122, that is, the second memory cell control signal Sgn_CONT2 (S150). That is, the PIM block 120 may perform the internal processing operation corresponding to the instruction, according to the instructions stored in the instruction register 121. Since this is the same as that described referring to FIGS. 5 and 6, the description thereof will not be repeated as redundant.

On the other hand, for example, when the operating mode of the memory device 100 is the general mode (NO of S140), the memory device 100 may perform the data transaction on the basis of the command decoded by the command decoder 110. That is, on the basis of the command decoded by the command decoder 110, the data provided from the memory controller 10 may be written to the memory cell array 180, or the data stored in the memory cell array 180 may be read and provided to the memory controller 10 (S160).

On the other hand, the PIM block 120 may determine where to transmit the data generated after the internal processing operation is performed to the exterior or the memory cell array (S170). That is, the data output unit 123 may transmit the data subjected to the internal processing operation to either the memory cell array 180 or the exterior by the control of the command generator 122.

Subsequently, when the internal processing operation is completed, it is determined whether there is another command/address CA received from the memory controller 10 (S180). As a result, when there is another command/address CA, it may be determined whether the command/address CA is in the general operating mode or the internal processing operating mode, and the corresponding operation may be performed (Yes of S180). On the other hand, when another command/address CA does not exist, the memory device 100 may transmit a completion signal to the memory controller 10 (S190).

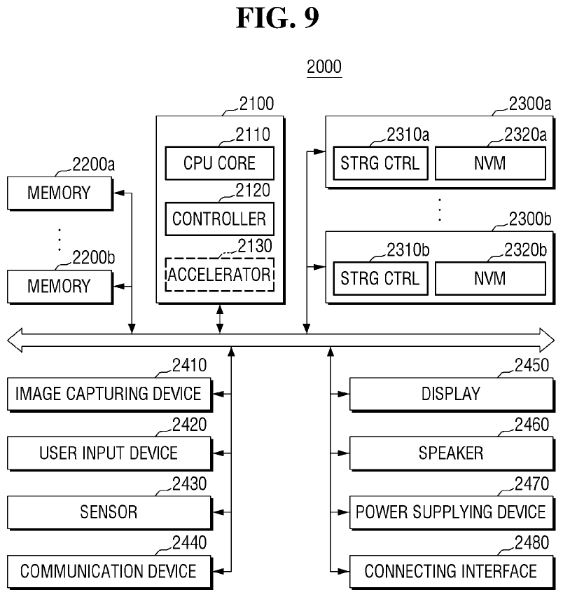

FIG. 9 is an exemplary block diagram for explaining a memory system according to some other embodiments.

Referring to FIG. 9, the memory system 2000 may be in essence a mobile system, such as a mobile phone, a smart phone, a tablet PC (tablet personal computer), a wearable device, a healthcare device or an IOT (internet of things) device.

However, the memory system 2000 of FIG. 9 is not necessarily limited to a mobile system, but may also be a personal computer, a laptop computer, a server, a media player, or an automotive device such as a navigation device.

Referring to FIG. 9, the memory system 2000 may include a main processor 2100, memories 2200a and 2200b, and storage devices 2300a and 2300b, and may additionally include one or more of an image capturing device 2410, a user input device 2420, a sensor 2430, a communication device 2440, a display 2450, a speaker 2460, a power supply device 2470, and a connecting interface 2480.

The memories 2200a and 2200b may be substantially the same as the memory device 100 described in FIGS. 1 to 8.

The main processor 2100 may control the overall operations of the memory system 2000, more specifically, the operations of other constituent elements that make up the memory system 2000. Such a main processor 2100 may be implemented as a general purpose processor, a dedicated processor, an application processor, or the like.

The main processor 2100 may include one or more CPU cores 2110, and may further include a controller 2120 for controlling the memories 2200a and 2200b and/or the storage devices 2300a and 2300b.

The controller 2120 may be substantially the same as the memory controller 10 described in FIGS. 1 and 2.

Depending on the different embodiments, the main processor 2100 may further include an accelerator 2130, which is a dedicated circuit for a high-speed data computation such as an AI (artificial intelligence) data computation. Such an accelerator 2130 may include a GPU (Graphics Processing Unit), an NPU (Neural Processing Unit) and/or a DPU (Data Processing Unit), and the like, and may be implemented as separate chips that are physically independent of other constituent elements of the main processor 2100.

The memories 2200a and 2200b may be used as a main memory unit of the memory system 2000, and may include a volatile memory such as an SRAM and/or a DRAM, but may also include a non-volatile memory such as a flash memory, a PRAM and/or a RRAM. The memories 2200a and 2200b may also be implemented as internal to the package of the main processor 2100.

The storage devices 2300a and 2300b may function as non-volatile storage devices for storing the data regardless of whether power is supplied, and may have a relatively larger capacity than the memories 2200a and 2200b. The storage devices 2300a and 2300b may include storage controllers 2310a and 2310b, and non-volatile memories (NVM) 2320a and 2320b that store data under the control of the storage controllers 2310a and 2310b. The non-volatile memories 2320a and 2320b may include a flash memory of a 2D (2-dimensional) structure or a 3D (3-dimensional) V-NAND (Vertical NAND) structure, but may also include other types of non-volatile memory such as a PRAM and/or a RRAM.

The storage devices 2300a and 2300b may be included in the memory system 2000 in a state of being physically separated from the main processor 2100, and may be implemented in the same package as the main processor 2100. Further, since the storage devices 2300a and 2300b have a form such as an SSD (solid state device) or a memory card, the storage devices 2300a and 2300b may also be detachably coupled with other constituent elements of the memory system 2000 through an interface such as a connecting interface 2480 to be described below. Such storage devices 2300a and 2300b may be, but are not necessarily limited to, devices to which standard protocols such as a UFS (universal flash storage), an eMMC (embedded multi-media card) or an NVMe (non-volatile memory express) are applied.

The image capturing device 2410 may capture still images or moving images, and may be a camera, a camcorder, and/or a webcam or the like.

The user input device 2420 may receive various types of data that are input from users of the memory system 2000, and may be a touch pad, a key pad, a key board, a mouse and/or a microphone etc.

The sensor 2430 may detect various types of physical quantities that may be acquired from the exterior of the memory system 2000, and convert the detected physical quantities into electrical signals. Such a sensor 2430 may be a temperature sensor, a pressure sensor, an illuminance sensor, a position sensor, an acceleration sensor, a biosensor and/or a gyroscopic sensor.

The communication device 2440 may transmit and receive signals to and from other devices external to the memory system 2000 according to various communication protocols. Such a communication device 2440 may be implemented to include an antenna, a transceiver and/or a modem and the like.

The display 2450 and the speaker 2460 may each function as output devices that output visual and auditory information to the user of the memory system 2000.

The power supply device 2470 may appropriately convert the power supplied from a battery (not shown) equipped in the memory system 2000 and/or an external power supply and supply the power to each of the constituent elements of the memory system 2000.

The connecting interface 2480 may provide a connection between the memory system 2000 and an external device that may be connected to the memory system 2000 to transmit and receive data to and from the memory system 2000. The connecting interface 2480 may be implemented by various interface types, such as an ATA (Advanced Technology Attachment), a SATA (Serial ATA), an e-SATA (external SATA), a SCSI (Small Computer Small Interface), a SAS (Serial Attached SCSI), a PCI (Peripheral Component Interconnection), a PCIe (PCI express), a NVMe, an IEEE 1394, a USB (universal serial bus), an SD (secure digital) card, a MMC (multi-media card), an eMMC, a UFS, an eUFS (embedded Universal Flash Storage), and a CF (compact flash) card interface.

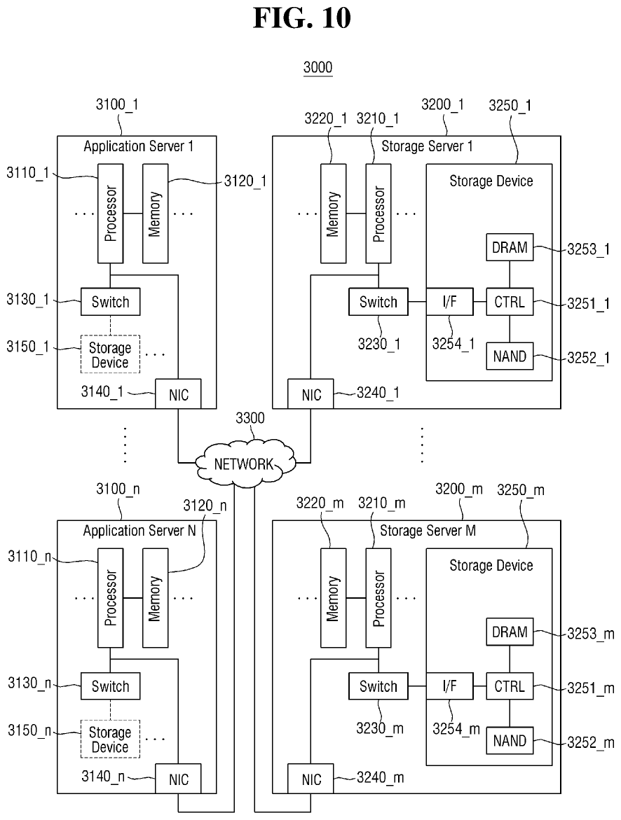

FIG. 10 is an exemplary block diagram which shows a data center according to some embodiments.

Referring to FIG. 10, a data center 3000 is a facility that gathers various types of data and provides services, and may also be referred to as a data storage center.

The data center 3000 may be a system for a search engine and database operation, and may be a computing system used by corporations such as banks or government agencies. The data center 3000 may include application servers 3100 to 3100n and storage servers 3200 to 3200m. The number of application servers 3100 to 3100n and the number of storage servers 3200 to 3200m may be variously selected depending on the particular embodiments, and the number of application servers 3100 to 3100n and the number of storage servers 3200 to 3200m may be different from each other.

The application server 3100 or the storage server 3200 may include at least one of the processors 3110 and 3210 and the memories 3120 and 3220. The storage server 3200 will be described as an example. The processor 3210 may control the overall operation of the storage server 3200, and access the memory 3220 to execute command and/or data loaded into the memory 3220.

The memory 3220 may be a DDR SDRAM (Double Data Rate Synchronous DRAM), a HBM (High Bandwidth Memory), a HMC (Hybrid Memory Cube), a DIMM (Dual In-line Memory Module), an Optane DIMM or a NVMDIMM (Non-Volatile DIMM).

The memory 3220 may be substantially the same as the memory device 100 described in FIGS. 1 to 8.

According to various embodiments, the number of processors 3210 and the number of memories 3220 included in the storage server 3200 may be variously selected. In an embodiment, the processor 3210 and the memory 3220 may provide a processor-memory pair. In a further embodiment, the number of processors 3210 and memories 3220 may be different from each other. The processor 3210 may include a single core processor or a multi-core processor.

The aforementioned explanation of the storage server 3200 may also be similarly applied to the application server 3100. According to an embodiment, the application server 3100 may not include a storage device 3150. The storage server 3200 may include at least one or more storage devices 3250. The number of storage devices 3250 included in the storage server 3200 may be variously selected depending on the particular embodiments.

Embodiments of the present disclosure have been described above with reference to the accompanying drawings, but the present disclosure is not limited thereto and may be implemented in various different forms. It will be understood that the present disclosure can be implemented in other specific forms without modifying the spirit and scope of the present disclosure. Therefore, it should be understood that the embodiments set forth herein, are illustrative only in all respects and not limiting.

What is claimed is:

1. A memory device comprising:
a memory cell array configured to store data;
a command decoder configured to receive command from the outside to generate a first memory cell control signal;
a PIM (Processor In Memory) block configured to generate a second memory cell control signal including a command for performing an internal processing operation on the basis of instructions stored therein and perform an internal processing operation on the basis of the second memory cell control signal; and
an operating mode multiplexer configured to output any one of the first memory cell control signal and the second memory cell control signal and provide the same to the memory cell array.

2. The memory device of claim 1, wherein in response to the operating mode multiplexer outputting the first memory cell control signal, the command decoder writes data provided from the exterior to the memory cell array on the basis of the first memory cell control signal, or reads data stored in the memory cell array and provides it to the exterior.

3. The memory device of claim 1, wherein in response to the operating mode multiplexer outputting the second memory cell control signal, the PIM block reads data for performing the internal processing operation from the memory cell array on the basis of the second memory cell control signal or writes data for which the internal processing operation is completed for use by the memory cell array.

4. The memory device of claim 3, wherein the PIM block further includes receiving data from the exterior, and
wherein receiving the data from the exterior and reading of the stored data from the memory cell array by the PIM block are performed at substantially the same time point.

5. The memory device of claim 1, wherein the PIM block includes an instruction register that stores the instructions for instructing the performance of each of particular internal processing operations in a pre-coded state, and
a command generator that receives the instructions from the instruction register and generates the second memory cell control signal on the basis of the instructions.

6. The memory device of claim 5, wherein the PIM block further includes a data output unit, and
the data output unit transmits data for which the internal processing operation is completed to any one of the exterior or the memory cell array by control of the command generator.

7. The memory device of claim 1, wherein the internal processing operation includes a MAC (Multiplying-Accumulating) computation.

8. The memory device of claim 1, wherein the memory cell array includes a plurality of volatile memory cells.

9. A memory device comprising:
a PIM (Processor In Memory) block configured to include an instruction register configured to store instructions for instructing the performance of each of particular internal processing operations in a pre-coded state, and a command generator configured to receive the instructions from the instruction register and generate a first memory cell control signal on the basis of the instructions,
wherein the PIM block reads data for performing the internal processing operation on the basis of the first memory cell control signal from a memory cell array,
the PIM block performs the internal processing operation, and
the PIM block writes data for which the internal processing operation is completed for use by the memory cell array.

10. The memory device of claim 9, wherein the PIM block further includes a data output unit, and
the data output unit transmits data for which the internal processing operation is completed to either the exterior or the memory cell array by control of the command generator.

11. The memory device of claim 9, further comprising:
a memory cell array configured to store data;
a command decoder configured to receive a command from the exterior to generate a second memory cell control signal; and
an operating mode multiplexer configured to output any one of the first memory cell control signal or the second memory cell control signal and provide it to the memory cell array.

12. The memory device of claim 11, wherein in response to the operating mode multiplexer outputting the second memory cell control signal, the command decoder writes data provided from outside to the memory cell array on the basis of the second memory cell control signal, or reads data stored in the memory cell array and provides the data to the exterior.

13. The memory device of claim 9, wherein the PIM block further includes reception of data from the exterior,
reception of the data from the exterior by the PIM block and reading of the data stored in the memory cell array are performed at substantially the same time point.

14. The memory device of claim 9, wherein the internal processing operation includes a MAC (Multiplying-Accumulating) computation.

15. The memory device of claim 9, wherein the memory cell array includes a plurality of volatile memory cells.

16. A memory system comprising:
a memory controller configured to provide a command and an address; and
a memory device configured to receive the command and the address from the memory controller and transmit and receive data to and from the memory controller,
wherein the memory device includes
a memory cell array that stores data, and
a PIM (Processor In Memory) block that generates a first memory cell control signal including a command for performing an internal processing operation on the basis of instructions stored therein, and performs the internal processing operation on the basis of the first memory cell control signal,
wherein the PIM reads data for performing the internal processing operation on the basis of the first memory cell control signal from the memory cell array or writes data for which the internal processing operation is completed for use by the memory cell array.

17. The memory system of claim 16, wherein the memory device further includes
a command decoder that receives the command to generate a second memory cell control signal, and
an operating mode multiplexer that outputs any one of the first memory cell control signal or the second memory cell control signal and provides it to the memory cell array.

18. The memory system of claim 17, wherein in response to the operating mode multiplexer outputting the second memory cell control signal, the command decoder writes the data provided from the memory controller to the memory cell array on the basis of the second memory cell control signal or reads the data stored in the memory cell array and provides the data to the memory controller.

19. The memory system of claim 16, wherein the internal processing operation includes a MAC (Multiplying-Accumulating) computation.

20. The memory system of claim 16, wherein the memory device includes a DRAM (Dynamic Random Access Memory).
